(19) United States
(12) Patent Application Publication
(10) Pub. No.: US 2024/0188374 A1
(43) Pub. Date: Jun. 6, 2024

(54) PINNED PHOTODIODE SENSOR

(71) Applicant: ams-OSRAM Asia Pacific Pte. Ltd., Singapore (SG)

(72) Inventors: Benjamin Joseph SHEAHAN, Eindhoven (NL); Robert VAN ZEELAND, Eindhoven (NL); Kirk David PETERSON, Eindhoven (NL); Wern Ming KOE, Eindhoven (NL); George Richard KELLY, Eindhoven (NL); Mario MANNINGER, Eindhoven (NL)

(21) Appl. No.: 18/278,591

(22) PCT Filed: Dec. 21, 2021
(86) PCT No.: PCT/SG2021/050810

§ 371 Date: Aug. 23, 2023

Related U.S. Application Data
(60) Provisional application No. 63/152,926, filed on Feb. 24, 2021.

(51) Int. Cl. H10K 59/65

(52) U.S. Cl. CPC H10K 59/65

(57) ABSTRACT

A sensor for ambient light and/or color sensing includes a pixel and circuitry. The pixel includes a plurality of pinned photodiodes selectively coupled to a floating diffusion region. The circuitry is configurable to select an integration time and to couple one or more of the plurality of pinned photodiodes to the floating diffusion region in response to a sensed intensity of radiation incident on the pixel.

### FIELD OF DISCLOSURE

The present disclosure is in the field of ambient light and color sensing, and in particular relates to ambient light and color sensors implemented with pinned photodiodes.

### BACKGROUND

Radiation sensors are commonly used in electronic devices such as smartphones, smart-watches, tablet devices and laptop computers. Such devices typically have displays, e.g. LED screens, for presenting information to a user. Furthermore, such electronic devices may also comprise image-sensing devices, such as cameras.

An effectiveness of displays in presenting information to a user may be influenced by ambient radiation. For example, in bright environments characterized by a high intensity of ambient radiation, it may be desirable to increase a brightness of the display to increase an overall perceptibility of displayed information. Conversely, in low light environments characterized by a low intensity of ambient radiation, it may be desirable to decrease a brightness of the display to avoid irritation to a user's eyes.

Similarly, an ability for a device to capture an image and/or display a captured image may also be affected by ambient radiation levels. In particular, a color of ambient radiation may affect an ability of an image-sensing device to perform white-balancing of an image.

Radiation sensors may provide detailed information about an ambient radiation level. For example, one or more radiation sensors may generally be implemented on such electronic devices to enable the device to adapt a brightness of a display in response to a detected ambient radiation level. However, existing radiation sensors may exhibit a limited dynamic range, thus limiting their suitability for accurately sensing ambient radiation levels across a wide range of lighting conditions, e.g. ranging from strong direct sunlight to low-light conditions.

Radiation sensors may also provide information about a color of incident radiation. Information about the color of incident radiation may enabled features such as auto-white-balancing (AWB) of images captured by a camera and/or adjustment of a display of images in response to a sensed color and/or intensity of ambient radiation. Furthermore, information about the color of incident radiation may enable classification of an ambient radiation source.

Sensing of ambient radiation may be known in the art as Ambient Light Sensing (ALS). In the context of ambient radiation, the term ‘light’ will be understood to encompass visible and/or non-visible radiation, e.g. infrared and/or ultraviolet radiation. A requirement of ALS is to detect ambient radiation intensity levels and/or colors with a relatively high degree of accuracy. Existing radiation sensors may be limited in their ability to distinguish between different colors of incident radiation.

A recent trend in portable device design, and in particular in the design of smartphones, is to maximize a display area by reducing an area of a bezel. This may be achieved, at least in part, by positioning sensors such as radiation sensors behind the display.

By mounting a sensor behind a display, an intensity of radiation incident upon the sensor may be reduced due to a degree of opacity of the display. Furthermore, in some instances the display itself may emit radiation that may interfere with measurements of radiation by sensors disposed behind the display.

It is therefore desirable to provide a sensor suitable for disposal behind a display of a portable device that exhibits a high level of optical sensitivity with high accuracy, while also being characterized by a relatively low ‘dark-count’, e.g. a low signal level in the absence of incident radiation.

Furthermore, it is also desirable to provide a sensor exhibiting a wide dynamic range suitable for use across a full range of ambient radiation conditions, such as direct sunlight and low-light conditions.

Requirements in low-power, performance and miniaturization have also driven a necessity for a high degree of integration of components in such electronic devices. With such integration and miniaturization, a susceptibility of sensors to the effects of noise, and in particular power-supply noise, may be increased. It is therefore also desirable to provide a highly integratable sensor exhibiting a high degree of immunity to noise, and in particular having a high Power-Supply-Rejection-Ration (PSRR).

It is therefore an aim of at least one embodiment of at least one aspect of the present disclosure to obviate or at least mitigate at least one of the above identified shortcomings of the prior art.

### SUMMARY

The present disclosure is in the field of ambient light and color sensing, and in particular relates to sensors implemented with pinned photodiodes. According to a first aspect of the disclosure, there is provided a sensor for ambient light and/or color sensing comprising: a pixel comprising a plurality of pinned photodiodes selectively coupled to a floating diffusion region. The sensor also comprises circuitry configurable to select an integration time and to couple one or more of the plurality of pinned photodiodes to the floating diffusion region in response to a sensed intensity of radiation incident on the pixel.

Advantageously, instead of using large n-well based photodiodes or even island photodiodes, as conventional ambient light sensors may do, the present disclosure relates to a sensor implementation that uses pinned photodiodes to achieve high sensitivity yet low noise measurements of a color and/or intensity of incident radiation.

Advantageously, the use of pinned photodiodes enables adaptation of a technology normally associated with image sensors and readily manufactured in a low-voltage CMOS compatible process.

Pinned photodiodes as conventionally implemented in such image sensors do not exhibit the necessary dynamic range and linearity of response that is required for accurate ambient light and color sensing. Advantageously, the disclosed sensor overcomes the shortcoming of the prior art by adapting both the integration time and an amount of photodiodes coupled to the floating diffusion region in response to a sensed intensity of radiation incident on the pixel, thereby ensuring that the pinned photodiodes sense radiation within an optimal range of operation of the pinned photodiodes. Thus the pinned photodiodes in the disclosed sensor achieve a sufficient dynamic range and linearity of response for ambient light and/or color sensing applications.

For example, in low incident radiation intensity conditions, the circuitry may be configured to couple a relatively large amount, e.g. a maximum amount, of pinned photodiodes to the floating diffusion. Conversely, in high incident radiation intensity conditions, the circuitry may be configured to couple a relatively low amount, e.g. a minimum amount, of pinned photodiodes to the floating diffusion. Similarly, an integration time may be reduced in high incident radiation intensity conditions or increased in low incident radiation intensity conditions to ensure the pinned photodiodes operate within an optimal range, as described in more detail below.

The circuitry may comprise a feedback circuit and/or feedback loop. The circuitry may comprise control circuitry configured to implement proportional control, proportional-integral control or proportional-integral-derivative control to determine an integration time and/or an amount of the plurality of pinned photodiodes to couple to the floating diffusion region in response to a sensed intensity of radiation incident on the pixel.

Advantageously, the use of pinned photodiodes enables extremely fast sensing of incident radiation, relative to sensing radiation with a conventional n-well ‘slab’ photodiode.

The integration time may be selected such that a charge accumulated by the one or more pinned photodiodes is less than 75% of a full-well-charge capacity of each of the pinned photodiodes.

In some embodiments, the integration time may be selected such that a charge accumulated by the one or more pinned photodiodes is less than 70%, less than 60%, less than 55% or less than 50% of a full-well-charge capacity of each of the pinned photodiodes. A precise threshold may, for example, be selected based upon characteristics of the photodiodes.

Advantageously, by limiting an accumulated charge to a level substantially below a full-well-charge capacity of the pinned photodiodes, the pinned photodiodes may operate predominantly within a range wherein a response is relatively linear. That is, a charge accumulated and stored in a pinned photodiode due to a photo-electric effect induced by incident radiation may be non-linear over a full range of the capacity of the pinned photodiode. In particular, a relationship between the amount of accumulated charge versus incident photon flux may become increasingly non-linear as the accumulated charge approaches the full-well capacity of the pinned photodiodes.

Advantageously, limiting an accumulated charge to a level below a full-well-charge capacity of the pinned photodiodes also avoids saturation of the pinned photodiodes, thus minimizing errors in measurements of an intensity of incident radiation. Furthermore, advantageously a dynamic range of the overall sensor may be maximized because saturation of the pinned photodiodes, or use of the pinned photodiodes in a non-liner range of operation.

Thus, the disclosed sensor overcomes the technical issues of non-linearity and limited dynamic range that would prohibit the use of pinned photodiodes for ambient radiation and/or color sensing applications.

The sensed intensity of radiation incident on the pixel may be determined by the circuitry using data from a plurality of separate integrations.

Advantageously, errors may be reduced by adapting an integration time and an amount of pinned photodiodes coupled to the floating diffusion in response to a sensed intensity of radiation incident on the pixel across multiple measurements.

In some embodiments, multiple integrations are sampled and converted into digital signals, wherein the digital signal, e.g. data, may be processed within the digital domain.

The circuitry may comprise a filter. For example, the circuitry may comprise one or more digital filters configured to filter data from a plurality of separate integrations

The integration time may be 150 microseconds or less.

Advantageously, such a short integration time, in particular when coupled with a relatively large active area of the pinned photodiodes in comparison to pinned photodiodes that may otherwise be implemented in image sensors, provides high sensitivity with a low dark-count. Furthermore, relatively to ambient light and/or color sensors implementing conventional n-well photodiodes, the disclosed pinned-photodiode-based sensors provide extremely fast measurements of ambient light and/or a color of incident radiation.

Advantageously, a relatively short integration time of 150 us or less may be particularly suited to applications wherein operation of the sensor must be synchronized with an LED screen, as described in further detail below.

Each pinned photodiode may comprise an active region having an area of at least 25 μm².

Advantageously, such a large area improves an overall sensitivity of the photodiodes. Furthermore, an area of at least 25 μm² is substantially larger than an area of a pinned photodiode as implemented in a conventional image sensor.

The pixel may comprise four pinned photodiodes arranged around the floating diffusion region.

The four pinned photodiodes may be arranged in a grid or array, with the floating diffusion region disposed substantially towards a central region of the pixel.

Advantageously, a total area of the pixel may be in the region of 12 μm×12 μm, resulting in a highly sensitive yet scalable architecture.

The sensor may comprise a plurality of pixels. The circuitry may be configured to average a signal from each pixel of the plurality of pixels prior to analog-to-digital conversion.

For example, in some embodiments, the sensor may comprise a plurality of pixels arranged in arrays. Advantageously, use of pinned photodiodes arranged in pixels provides a scalable architecture, and therefore is particularly suited to implementations of multi-channel sensors.

Advantageously, averaging the signals from a plurality of pixels may result in reduced noise.

In some embodiments, averaging of a signal from each of the pixels may be performed by the circuitry in the digital domain. Furthermore, it will be understood that, in addition to or as an alternative to averaging, filtering such as filtering with an FIR filter, may be performed on the signals from a plurality of pixels.

The sensor may comprise a plurality of channels. Each channel may comprise at least one pixel.

For purposes of example only, in some embodiments, each channel may comprise an array of 6×24 pixels. Each pixel may comprise four pinned photodiodes and a single floating diffusion region. The circuitry may comprise sample and hold circuitry associated with each channel. The circuitry may comprise one or more analogue to digital converters or comparators. The circuitry may be configured to sample each channel at a rate that depends upon the integration time.

The circuitry may comprise a memory for storing one or more results from the analogue to digital converters.

Each channel may be configured to sense a different range of wavelengths of radiation.

In some embodiments the sensor may comprise channels configured to sense a range of wavelengths of radiation spanning the visible range, e.g. approximately 400 nanometers to 700 nanometers. In some embodiments, the sensor may comprise channels configured to sense a range of wavelengths of radiation spanning the ultraviolet range and/or near infrared range.

In some embodiments, the sensor may comprise in the region of 100 channels.

Each channel may comprise an interference filter configured as a band-pass filter.

For example, the sensor may comprise a plurality of interference filters, each interference filter formed over one or more pixels, to define a multi-spectral sensor configurable to sense a plurality of colors of radiation. In some embodiments, such an interference filter may be formed on a backside of the sensor, as described in more detail below.

The sensor may be formed as a monolithic device in a low-voltage CMOS process.

Advantageously the use of pinned-photodiodes enables use of a low-voltage CMOS process, thereby enabling the pinned photodiodes to be fully integrated on-chip with the circuitry, such as processing circuitry and/or analogue circuitry.

The floating diffusion region may be configured to have a capacitance of 2.5 Femtofarads, or less.

Advantageously, such a low capacitance, in combination with the above-described relatively short integration times, may provide a relatively high conversion gain. For example, in some embodiments, a conversion gain of 80 pV/e- or greater may be achieved.

The sensor may be configured to exhibit a resolution of at least 18 bits.

The sensor may be configured to exhibit at least 27 bits of dynamic range.

Advantageously, by implementing the sensor with pinned photodiodes, and by overcoming the shortcomings of limited dynamic range and non-linearity that may otherwise be associated with pinned photodiodes as described above, e.g. with large area, short integration times, low capacitance and thus high conversion gain, the sensor is suitable for use in ambient light and/or color sensing applications with adequate resolution and dynamic range.

According to a second aspect of the disclosure, there is provided an electronic device comprising the sensor of the first aspect.

The electronic device may be a smartphone, tablet device, smart-watch, a laptop device, a personal computer, a camera, or a television. The device may be configured to receive and/or transmit a signal.

The sensor may be configured for backside-illumination.

That is, the sensor may be arranged within the electronic device such that radiation to be sensed is incident on a backside of the sensor. As such, in some embodiments, the radiation to be sensed may propagate through a substrate on which the sensor is formed.

Advantageously, by making use of backside illumination, enhanced sensitivity may be achieved while avoiding optical losses, especially at wavelengths of approximately 425 nanometers, e.g. blue light, due to nitride isolation layers implemented in advanced CMOS metal systems.

The electronic device may comprise an LED display. The sensor may be disposed rearward of a radiation-emitting surface of the LED display and configured and receive radiation propagating through the LED display.

Advantageously, the sensor may be suitable for use in Behind-OLED (BOLED) applications

In some embodiments, operation of the sensor may be synchronized with the LED display. For example, the sensor may be configured to sense radiation propagating through the LED display without interference from radiation emitted by the LED display.

The above summary is intended to be merely exemplary and non-limiting. The disclosure includes one or more corresponding aspects, embodiments or features in isolation or in various combinations whether or not specifically stated (including claimed) in that combination or in isolation. It should be understood that features defined above in accordance with any aspect of the present disclosure or below relating to any specific embodiment of the disclosure may be utilized, either alone or in combination with any other defined feature, in any other aspect or embodiment or to form a further aspect or embodiment of the disclosure.

### BRIEF DESCRIPTION OF THE PREFERRED EMBODIMENTS

These and other aspects of the present disclosure will now be described, by way of example only, with reference to the accompanying drawings, wherein:

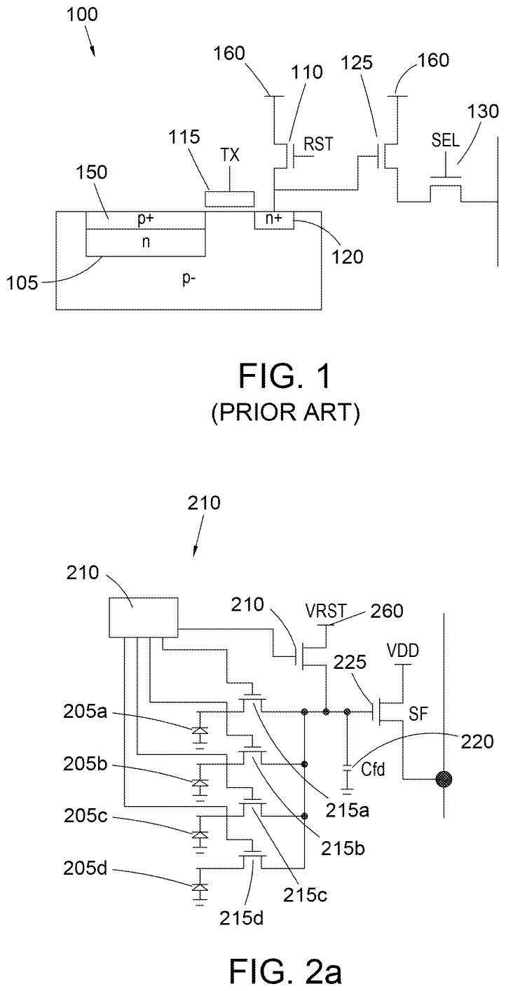

FIG. 1 depicts a representation of a prior art four transistor (4T) pinned photodiode pixel;

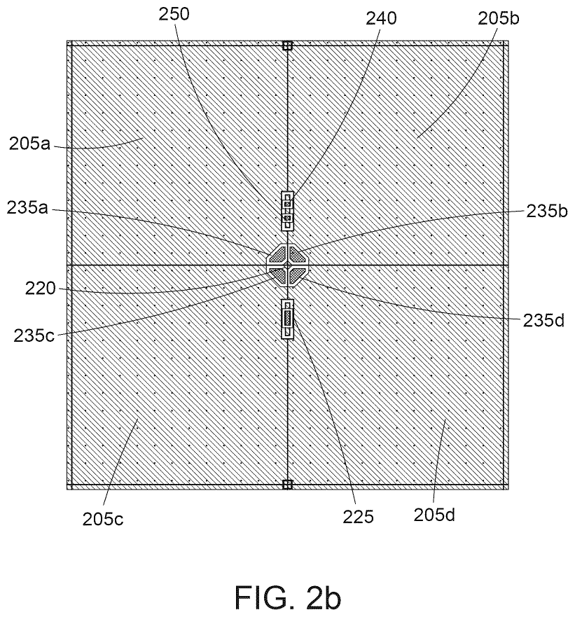

FIG. 2a depicts a schematic diagram of a pixel according to an embodiment of the present disclosure;

FIG. 2b depicts a plan view of a pixel according to an embodiment of the present disclosure;

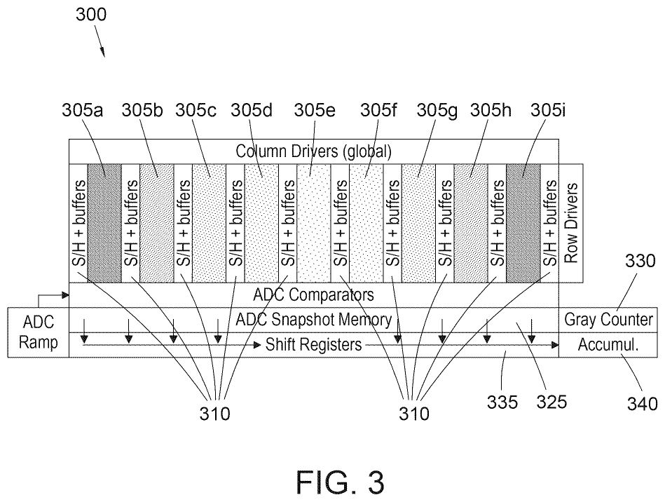

FIG. 3 depicts a block diagram of a sensor according to an embodiment of the disclosure;

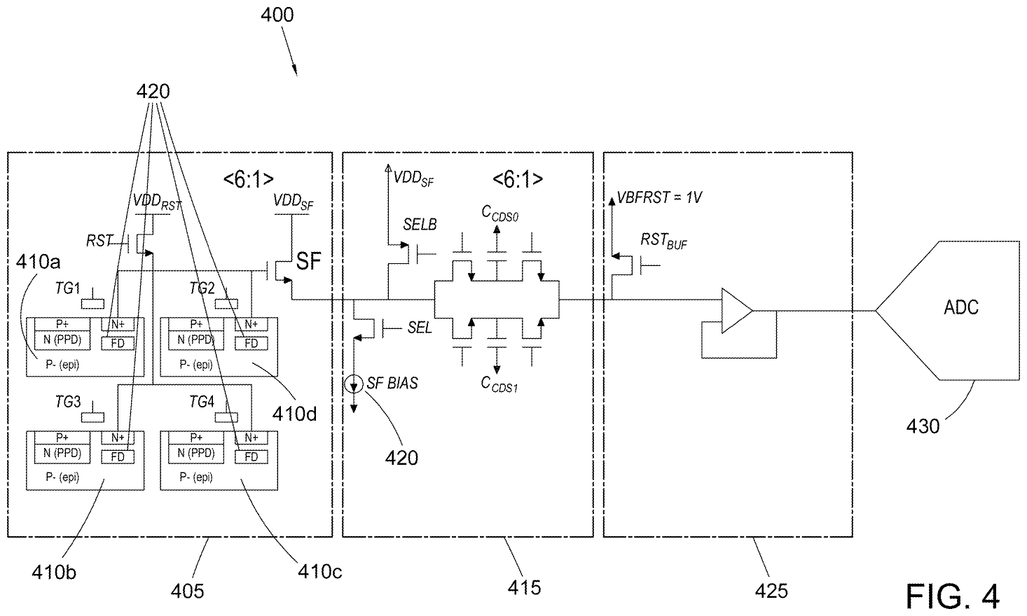

FIG. 4 depicts a circuit diagram representing a portion of a sensor according to an embodiment of the disclosure;

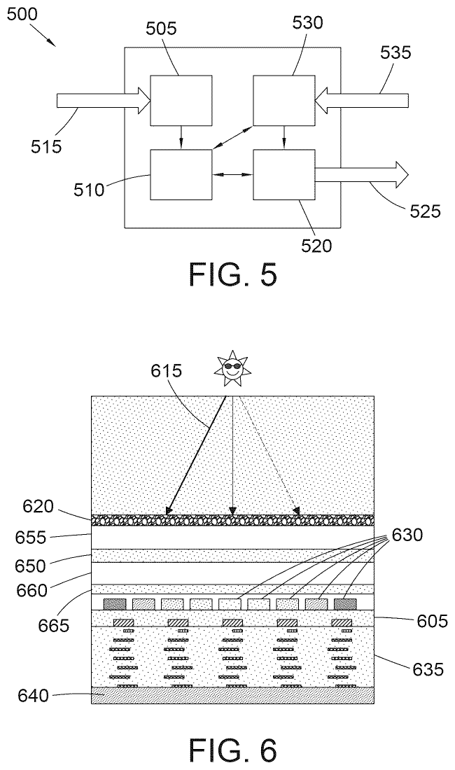

FIG. 5 an electronic device according to an embodiment of the disclosure; and

FIG. 6 a sensor according to an embodiment of the disclosure, implemented in a BOLED display application.

### DETAILED DESCRIPTION

FIG. 1 depicts a representation of a prior art four transistor (4T) active pixel, generally denoted 100, as may commonly be implemented in an image sensor. The active pixel 100 comprises a photodiode 105, a reset transistor 110, a transfer transistor 115, a source follower transistor 125, and a row select transistor 130.

For purposes of example, a CMOS structure of the photodiode 105 and the transfer transistor 115 are depicted. For simplicity, the reset transistor 110, the source follower transistor 125 and the row select transistor 130 are shown as symbolic representations of transistors.

The photodiode 105 comprises a p-n junction diode configured to be exposed to radiation and to convert incident radiation into a voltage signal though a process of optical absorption. The principles of generation of electron-hole pairs by optical absorption are well known, and will not be described here for reasons of expediency.

The photodiode 105 in active pixel 100 is a pinned photodiode. That is, the photodiode 105 has been passivated with a shallow p+ implant, known as a pinning layer, above a radiation-sensitive structure of the photodiode 105. The pinning layer 150 permits a total transfer of charge onto an n floating diffusion region 120 under the control of the transfer transistor 115, as will be described below. Again, pinned photodiodes are well known in the art and will not be further described at this juncture.

The transfer transistor 115 comprises the floating diffusion region 120. The transfer transistor 115 is configured to move a charge from the photodiode 105 to the floating diffusion region 120.

The reset transistor 110 is coupled between the voltage reference 160 and the floating diffusion region 120 to reset the active pixel 100, e.g., discharge or charge the floating diffusion region 120 and the photodiode 105 to a reset voltage under control of the reset transistor 110.

The source follower transistor 125 is operated effectively as a voltage buffer. An input voltage, e.g. a voltage at a gate of the source follower transistor 125, corresponds to a voltage of the floating diffusion region 120. An output of the source follower transistor 125, e.g. the source terminal of the source follower transistor 125, generally corresponds to the voltage at the gate of the source follower transistor 125, minus a voltage dropped across the source follower transistor 125. Beneficially, the source follower transistor 125 does not draw a substantial current from the floating diffusion region 120, thus allowing a measurement of a voltage at the floating diffusion region 120 without discharging the floating diffusion region 120.

The row select transistor 130 selectively couples the voltage at the source of the source follower transistor 125 to a further circuit, typically comprising measurement circuitry such as an ADC, to measure the effective voltage at the floating diffusion region 120. In use, the voltage at the floating diffusion region 120 corresponds to a charge stored at the floating diffusion region 120, and thus is indicative of an intensity of light which the photodiode has been exposed to over an integration time.

A typical mode of operation of the prior art 4T active pixel 100 is as follows.

In an initial stage of operation, a reset signal RST is asserted at a gate of the reset transistor 110 and a transfer signal TX is asserted at a gate of the transfer transistor 115. By simultaneously turning on the reset transistor 110 and the transfer transistor 115, the floating diffusion region 120 and the photodiode 105 are connected to the voltage reference 160, e.g. a power supply rail. This condition represents a reset state of the active pixel 100. That is, the voltage reference 160 provides a reset voltage for the active pixel 100.

Next, the transfer signal TX is negated at the gate of the transfer transistor 115, effectively turning off the transfer transistor 115 and the reset signal RST is negated at the gate of the reset transistor 110 to turn off the reset transistor 110, thus electrically isolating the photodiode 105 from the voltage reference 160.

At this stage, the photodiode 105 may be exposed to light, and will commence accumulation of charge accordingly. That is, an integration time is commenced by negating the transfer signal TX and permitting incident light to charge the photodiode 105. As photo-generated electrons accumulate in the photodiode 105, a voltage at the photodiode 105 decreases.

After the integration time the level of accumulated charge and hence the amount of radiation incident upon the photodiode 105 may be determined as follows.

The reset signal RST may be asserted at the gate of the reset transistor 110 to reset the floating diffusion region 120 to the voltage reference 160. In any event, at the end of the integration time, the reset signal RST is de-asserted to isolate the floating diffusion region 120.

Next, the transfer signal TX is temporarily asserted at a gate of the transfer transistor 115 to allow the accumulated charge on the photodiode 105 to be transferred to the floating diffusion region 120. That is, the photodiode 105 is temporarily coupled to the floating diffusion region 120, and hence to a gate of the source follower transistor 125. The charge transfer causes the voltage of the floating diffusion region 120 to drop from the voltage reference 160 to a second voltage indicative of an amount of charge accumulated on the photodiode 105 during the integration time.

Upon completion of the charge transfer, the row select transistor 130 is configured to couple the voltage at the source of the source follower transistor 125 to a further circuit, typically comprising a ramp-ADC (not shown).

FIG. 2a depicts a circuit diagram of a pixel 200 according to an embodiment of the present disclosure. The pixel 200 comprises a plurality of pinned photodiodes 205a, 205b, 205c, 205d, a reset transistor 210, a plurality of transfer transistors 215a, 215b, 215c, 215d, and a source follower transistor 225. In the circuit of FIG. 2a, each pinned photodiode 205a, 205b, 205c, 205d comprises a pinning layer above a radiation-sensitive structure, as described above with reference to FIG. 1.

The pixel 200 also comprises a floating diffusion region 220, which is represented as a capacitor in FIG. 2. In some embodiments the floating diffusion region 220 may be configured to have a capacitance of 2.5 Femtofarads, or less.

Circuitry 230 is coupled to a gate of each transfer transistor 215a, 215b, 215c, 215d and the reset transistor 210. The circuitry 230 is configurable to select an integration time and to couple one or more of the plurality of pinned photodiodes 205a, 205b, 205c, 205d to the floating diffusion region in response to a sensed intensity of radiation incident on the pixel 200, as described in more detail below. The circuitry 230 may, for example, comprise logic, a state machine and/or a processor. The circuitry 230 may be programmable circuitry.

In contrast to the prior art pixel 100 of FIG. 1, in the pixel 200 according to an embodiment of the present disclosure, all of the plurality of transfer transistors 215a, 215b, 215c, 215d are coupled to a single floating diffusion region 220.

That is: a first pinned photodiode 205a is selectively coupled to the floating diffusion region 220 by control of a gate of a first transfer transistor 215a; a second pinned photodiode 205b is selectively coupled to the floating diffusion region 220 by control of a gate of a second transfer transistor 215b; a third pinned photodiode 205c is selectively coupled to the floating diffusion region 220 by control of a gate of a third transfer transistor 215c; and a fourth pinned photodiode 205d is selectively coupled to the floating diffusion region 220 by control of a gate of a fourth transfer transistor 215d.

In some embodiments, the single floating diffusion region 220 forms a node of each of the transfer transistors 215a, 215b, 215c, 215d, e.g. the single floating diffusion region 220 may effectively form the source or drain of each of the transfer transistors 215a, 215b, 215c, 215d. As such, each transfer transistor 215a, 215b, 215c, 215d is configurable to move a charge from a pinned photodiode 205a, 205b, 205c, 205d to the floating diffusion region 220.

Similar to the prior art example of FIG. 1, the reset transistor 210 is coupled between a voltage reference 260 and the floating diffusion region 220 to reset the pixel 200, e.g., to discharge or charge the floating diffusion region 220 and the pinned photodiodes 205a, 205b, 205c, 205d to a reset voltage under control of the reset transistor 210. In the example embodiment of FIG. 2, the voltage reference 260 is a supply voltage, e.g. VDD.

The source follower transistor 225 operates effectively as a voltage buffer, as is described above with regard to the source follower transistor 125 of FIG. 1, and therefore is not described in further detail.

An output of the source follower transistor 225, e.g. the source, is coupled to measurement circuitry, such as an ADC, to measure the effective voltage at the floating diffusion region 220 as described in more detail below with reference to FIGS. 3 and 4.

In use, the voltage at the floating diffusion region 220 corresponds to a charge stored at the floating diffusion region 220, and thus is indicative of an intensity of radiation which the pinned photodiodes 205a, 205b, 205c, 205d have been exposed to over an integration time.

A mode of operation of the pixel 200 is as follows.

In some embodiments, at an initial stage of operation, a reset signal is asserted at a gate of the reset transistor 210 by the circuitry 230 and a transfer signal is asserted at a gate of each transfer transistor 215a, 215b, 215c, 215d by the circuitry 230. By simultaneously turning on the reset transistor 210 and the transfer transistors 215a, 215b, 215c, 215d, the floating diffusion region 220 and the plurality of pinned photodiodes 205a, 205b, 205c, 205d are connected to the voltage reference 260, e.g. a power supply rail. This condition represents a reset state of the pixel 200. That is, the voltage reference 260 provides a reset voltage for the pixel 200.

Next, the transfer signal is negated at the gate of at least one of the transfer transistors 215a, 215b, 215c, 215d by the circuitry 230, effectively turning off the selected transfer transistor 215a, 215b, 215c, 215d. Furthermore, the reset signal is also negated at the gate of the reset transistor 210 by the circuitry 230 to turn off the reset transistor 210, thus electrically isolating the pinned photodiodes 205a, 205b, 205c, 205d associated with the selected transfer transistor 215a, 215b, 215c, 215d from the voltage reference 260.

In some embodiments, the circuitry 230, which is coupled to the gate of each transfer transistor 215a, 215b, 215c, 215d, is configured to select which or how many, of the transfer transistors 215a, 215b, 215c, 215d are selected. For example, a selection may be made based upon a previous measurement of an intensity of radiation incident upon one or more of the pinned photodiodes 205a, 205b, 205c, 205d, as described below.

At this stage, the pinned photodiodes 205a, 205b, 205c, 205d may be exposed to radiation, and will commence accumulation of charge accordingly. That is, an integration time is commenced by negating the transfer signal to at least one of the transfer transistors 215a, 215b, 215c, 215d thereby enabling incident radiation to charge the selected pinned photodiodes 205a, 205b, 205c, 205d, e.g. those pinned photodiodes having their associated transfer transistor 215a, 215b, 215c, 215d turned off as described above. As photo-generated electrons accumulate in the selected pinned photodiodes 205a, 205b, 205c, 205d, voltages at the selected pinned photodiodes 205a, 205b, 205c, 205d decreases.

After the integration time, the level of accumulated charge and hence an indication of the amount of radiation incident upon the selected pinned photodiodes 205a, 205b, 205c, 205d may be determined as follows.

In some embodiments, the reset signal may be asserted at the gate of the reset transistor 210 to reset the floating diffusion region 220 to the voltage defined by the voltage reference 260. In any event, at the end of the integration time, the reset signal is de-asserted to isolate the floating diffusion region 220.

Next, the transfer signal is temporarily asserted by the circuitry 230 at a gate of the selected transfer transistors 215a, 215b, 215c, 215d to allow the accumulated charge on one or more of the pinned photodiodes 205a, 205b, 205c, 205d to be transferred to the floating diffusion region 220. That is, one or more of the pinned photodiodes 205a, 205b, 205c, 205d are temporarily coupled to the floating diffusion region 220, and hence to a gate of the source follower transistor 225. Charge transfer causes the voltage of the floating diffusion region 220 to drop from the voltage reference 260 to a second voltage indicative of an amount of charge accumulated on the one or more of the pinned photodiodes 205a, 205b, 205c, 205d during the integration time.

Upon completion of the charge transfer, further circuitry may be configured to measure a voltage at the source of the source follower transistor 225, as described in more detail below.

In contrast to the pixel 100 of FIG. 1, the embodiment of the disclosure shown as pixel 200 in FIG. 2 has four pinned photodiodes 205a, 205b, 205c, 205d coupled to a single floating diffusion region 220. The circuitry 230 may select which, and how many of the pinned photodiodes 205a, 205b, 205c, 205d are coupled to the floating diffusion region 220 for any integration. As such, operation of the pixel 200 can be optimized for a variety use cases. For example, in low incident radiation intensity conditions, the circuitry 230 may be configured to couple a relatively large amount, e.g. all four, of the pinned photodiodes 205a, 205b, 205c, 205d to the floating diffusion region 220. Conversely, in high incident radiation intensity conditions, the circuitry 230 may be configured to couple fewer pinned photodiodes 205a, 205b, 205c, 205d, e.g. one, two or three pinned photodiodes 205a, 205b, 205c, 205d to the floating diffusion region 220. That is, while the capacity of the floating diffusion region 220 to store a charge remains fixed, by selecting an appropriate amount of pinned photodiodes 205a, 205b, 205c, 205d in response to a previously sensed intensity of radiation incident on the pixel 200, an optimum usage of the floating diffusion region 220 may be made.

Similarly, the circuitry 230 may be configured to adjust the integration time, thereby also making optimum use of the floating diffusion region 220, and the storage capacity of the pinned photodiodes 205a, 205b, 205c, 205d. For example, the circuitry 230 may be configured to reduce the integration time in high incident radiation intensity conditions or increase the integration time in low incident radiation intensity conditions, to ensure the pinned photodiodes 205a, 205b, 205c, 205d operate within an optimal range. In some embodiments, the circuitry 230 may be configured to adapt the integration time in response to a previously sensed intensity of radiation incident on the pixel 200. For example, the circuitry 230 may be configured to avoid exceeding a charge storage capacity of each of the pinned photodiodes 205a, 205b, 205c, 205d.

In some embodiments, the integration time may be 150 μs or less.

A full-well charge capacity of the pinned photodiodes 205a, 205b, 205c, 205d may be known, or may be determined by a calibration process. For example, data corresponding to the full-well charge capacity of the pinned photodiodes 205a, 205b, 205c, 205d may be stored by the circuitry 230, and may be used to deermine a threshold against which measurements of a voltage corresponding to a charge stored on the pinned photodiodes 205a, 205b, 205c, 205d may be compared.

The circuitry 230 may be configured to determine whether any of the pinned photodiodes 205a, 205b, 205c, 205d have reached or nearly reach their full-well charge capacity.

Furthermore, the circuitry 230 may be configured to ensure that the pinned photodiodes 205a, 205b, 205c, 205d operate completely, or predominantly within a region wherein the pinned photodiodes 205a, 205b, 205c, 205d provide a linear response. For example, the circuitry 230 may select an integration time such that a charge accumulated by the one or more pinned photodiodes 205a, 205b, 205c, 205d is substantially less than the full-well-charge capacity of each of the pinned photodiodes 205a, 205b, 205c, 205d. In some embodiments, the circuitry 230 may select an integration time such that a charge accumulated by the one or more pinned photodiodes 205a, 205b, 205c, 205d is, for example, less than 75% of a full-well-charge capacity. In some embodiments, the threshold may be set lower, for example 65%, 60%, 55%, or even as low as 50%. By limiting an accumulated charge to such levels substantially below the full-well-charge capacity of the pinned photodiodes 205a, 205b, 205c, 205d, the pinned photodiodes 205a, 205b, 205c, 205d may operate predominantly within a range wherein their response is relatively linear.

In some embodiments, the circuitry 230 may comprise a feedback circuit and/or a feedback loop, e.g. means to adapt an integration time and/or an amount of the pinned photodiodes 205a, 205b, 205c, 205d to be coupled to the floating diffusion region 220 in response to a result of a previous integration. In some embodiments, the feedback loop may be implemented in software, e.g. in embodiments wherein the circuitry 230 comprises a processor.

FIG. 2b depicts a plan view of the pixel 200, according to an embodiment of the present disclosure. The pixel 200 comprises four pinned photodiodes 205a, 205b, 205c, 205d.

Also depicted in FIG. 2a are transfer gates 235a, 235b, 235c, 235d associated with each transfer transistor 215a, 215b, 215c, 215d respectively.

In a central area between the four pinned photodiodes 205a, 205b, 205c, 205d is the floating diffusion region 220. That is, the four pinned photodiodes 205a, 205b, 205c, 205d are arranged around the floating diffusion region 220.

Also depicted in FIG. 2a is a gate 240 associated with the reset transistor 210 and a gate 245 associated with the source-follower transistor 225.

For purposes of example only, a gate 250 associated with a dual conversion control transistor is also depicted. It will be understood that in some embodiments of the disclosure, the pixel 200 may comprise a dual conversion gain transistor included between the floating diffusion 220 and the reset transistor 210. Such a dual conversion gain transistor may enable an additional capacitance to be selectively coupled to the floating diffusion 220, thereby selectively increasing an effective charge storage capacity of the pixel 200, in certain conditions.

Notably, each pinned photodiode 205a, 205b, 205c, 205d comprise an active region having an area of at least 25 μm². Advantageously, such a large area improves an overall sensitivity of the photodiodes. Furthermore, an area of at least 25 μm² is substantially larger than an area of a pinned photodiode as implemented in an active pixel in a conventional image sensor, such as pixel 100 of FIG. 1.

FIG. 3 depicts a block diagram of an example sensor 300 according to an embodiment of the disclosure. For purposes of example only, the sensor 300 is a multi-spectral sensor suitable for color matching and ambient light-sensing applications, as described in more detail below.

The sensor 300 comprises a plurality of pixels arranged in channels 305a-i. Each channel 305a-i may comprise at least one pixel. The pixels in each channel 305a-i may, for example, be arranged in an array. Each pixel of each channel 305a-i is a pixel 200, as described above with reference to FIGS. 2a and 2b.

Each channel 305a-i of the sensor 300 is configured to sense a different range of wavelengths of radiation. It will be appreciated that in some embodiments of the sensor, a plurality of channels may be configured to sense partially or completely overlapping ranges of wavelengths of radiation.

In some embodiments the sensor 300 comprises channels 305a-i configured to sense a range of wavelengths of radiation spanning the visible range, e.g. approximately 400 nanometers to 700 nanometers. In some embodiments, the sensor 300 may comprise channels configured to sense a range of wavelengths of radiation spanning the ultraviolet range and/or near infrared range.

The example sensor 300 of FIG. 3 comprises 9 channels. In some embodiments, the sensor 300 may comprise fewer than 9 channels. In some embodiments, the sensor 300 may comprise substantially more than 9 channels, for example in the region of 100 channels.

Each channel 305a-i of the example sensor 300 comprises an interference filter configured as a band-pass filter. That is, each interference filter is formed over one or more pixels, as described in more detail below with reference to FIG. 4, to define a multi-spectral sensor configurable to sense a plurality of colors of radiation.

In one example embodiment, each channel 305a-I may comprise an array of 6×24 pixels. It will be understood that this is an example embodiment, and sensors with other arrangements of pixels may be provided. Furthermore, an amount of pixels may be the same, or may vary between the channels 305a-i of the sensor. As described above with reference to FIGS. 2a and 2b, each pixel may comprise four pinned photodiodes 205a, 205b, 205c, 205d and a single floating diffusion region 220.

Also depicted in FIG. 3 are row drivers and column drivers. The pixels or groups of pixels forming channels may be addressable using the row drivers and column drivers. For example, each pixel may have a row select transistor, in an arrangement similar to that depicted in the prior art 4T pixel of FIG. 1, e.g. row select transistor 130. Similarly, column select transistors (not shown) may be implemented for each pixel, group of pixels, or channel of pixels arranged in a column, thereby allowing particular pixels, groups of pixels or even complete channels of pixels to be addressed. In the example embodiment of FIG. 3, the column drivers are ‘global’ column drivers, configured to select an entire channel 305a-i. The sensor 300 comprises circuitry configured to control the row drivers and column drivers.

Also shown in FIG. 3 is sample and hold circuitry 310 associated with the channels 305a-i. The sample and hold circuitry 310 may be configured to sample a charge stored on the floating diffusion of a pixel, or group of pixels, or even an entire channel 305a-i, and to hold the measurement e.g. in a buffer, until such time as analogue to digital conversion of the measurement may be made.

In the example sensor 300 of FIG. 3, the sensor 300 comprises comparators 315 associated with the channels 305a-i. A ramp generator 320 is also depicted. An analogue to digital converter (ADC) may be realized by the ramp generator 320 providing a ramp signal that is compared to an output from the pixel(s) by the comparators 315. In the example ADC implementation of FIG. 3, a counter 330 is provided. To minimize any effects of noise in the circuitry, a gray counter 330 is implemented, although it will be appreciated that in other embodiments another counter, such as a binary counter, may be implemented. The circuitry may also comprise a memory 325, e.g. RAM or registers, for storing one or more results from the comparators 315.

The circuitry may be configured to latch a count from the gray counter, e.g. in the memory 325, upon a transition in an output of one or more of the comparators when comparing an output of the ramp generator 320 to a sampled charge stored on the floating diffusion of one or more pixels. In the example embodiment of FIG. 3, shift registers 335 may shift an ADC conversion to an accumulator 340, where a plurality of results of ADC conversions may be accumulated.

Circuitry, e.g. circuitry 260, may comprise the sample and hold circuitry 310, the comparators 315, the ramp generator 320, the memory 325, the counter 330, the shift registers 335 and the accumulator 340.

The circuitry may be configured to sample each channel 305a-i. at a rate that depends upon the integration time. In some embodiments, the circuitry may be configured to sample each channel 305a-I at a programmable rate.

The sensor 300 is formed as a monolithic device in a low-voltage CMOS process. That is, the pixels forming each channel 305a-i are formed on the same die as the circuitry, e.g. control circuitry and circuitry to provide analog to digital conversion, as described above.

FIG. 400 depicts a diagram of a circuit 400 representing a portion of a sensor, e.g. sensor 300, according to an embodiment of the disclosure.

The circuit 400 comprises a pixel 405. The pixel 405 corresponds to the pixel 200 of FIGS. 2A and 2B. The pixel 405 comprises four pinned photodiodes 410a, 410b, 410c, 410d. Although in FIG. 4 each of the four pinned photodiodes 410a, 410b, 410c, 410d depict a floating diffusion region, it will be appreciated that this is shown for illustrative purposes only, and the pixel 405 comprises only a single shared floating diffusion region 420. The single shared floating diffusion region 420 is shared between the four pinned photodiodes 410a, 410b, 410c, 410d, e.g. as depicted by the capacitor 220 in the pixel 200 of FIG. 2A.

The circuit 400 also comprises a sample and hold circuit 415. The sample and hold circuit 415 is a correlated double sampling circuit, enabling differencing of samples from the pixel(s) 405 to be taken before and after an integration time to reduce the effects of noise in the system.

Also depicted in the sample and hold circuit 415 is a current source 420 for biasing the source follower of the pixel 405.

The circuit 400 may be configured to accumulate and/or average a signal from each pixel of a plurality of pixels prior to analog-to-digital conversion. For example, in the circuit 400 of FIG. 4 only one pixel 405 is depicted. However, a plurality of pixels 405 may be coupled to the sample and hold circuitry 415. For example, and as denoted by “<6:1>” in FIG. 4, in the described embodiment six pixels 405 are coupled to the sample and hold circuit 415. For example, an output of the source-follower of six pixels 405 may be coupled to a column line, wherein the column line is coupled to the sample and hold circuitry.

The circuit 400 also comprises an output buffer 425 for maintaining a voltage level at an output of the circuit 400 prior to conversion by an ADC 430.

The sample and hold circuit 415 and the output buffer 425 may correspond to the sample and hold circuitry 310 of FIG. 3, as described above.

FIG. 5 depicts an electronic device 500 according to an embodiment of the disclosure. The electronic device 500 may be a smartphone, tablet device, smart-watch, a laptop device, a personal computer, a camera, or a television. The electronic device 500 may be a communications device, e.g. a device configured to receive and/or transmit a signal.

The example electronic device 500 comprises a sensor 505 for ambient light and/or color sensing. The sensor 505 is a sensor as described above with reference to FIGS. 2A, 2B, 3 and 4. The sensor 505 is configured to be exposed to incident radiation 515. One or more optical components (not shown), such as lenses, diffusers, polarizers, or the like may be provided between the sensor 505 and the source of incident radiation 515. In some embodiments, the sensor may be configured for backside-illumination, as described in more detail below with reference to FIG. 6.

Also depicted in FIG. 5 is a processor 510 coupled to the sensor 505. The processor may be configured to control the sensor and/or receive data from the sensor 505. The processor 510 may be configured to perform digital signal processing of data or a signal received from the sensor 505.

Although only a single processor 510 is depicted, it will be understood that the processor 510 may represent a plurality of processors.

In some embodiments, the processor 510 and the sensor 505 may be implemented as a monolithic device, e.g., a single integrated circuit device. In other embodiments, the sensor 505 may be provided as a separate device.

Also depicted in FIG. 5 is a display 520 such as an LED display configured to emit radiation 525, e.g. display an image. The processor 510 may be configured to control the display 520 to display an image.

In some embodiments, the processor 510 may be configured to adapt an image displayed by the display 520 in response to an ambient radiation 515 sensed by the sensor 505. For example, the processor 510 may be configured to brighten an image displayed by the display 520 in response to sensing a relatively high intensity of incident ambient radiation 515.

In some embodiments, the processor 510 may be configured to adapt an image displayed by the display 520 in response to a color of radiation 515 sensed by the sensor 505. For example, the processor 510 may be configured to identify or classify a light source based on a detected color of radiation 515 incident upon the sensor 505. In an example, the processor 510 may be configured to identify or classify a light source as a fluorescent, LED or incandescent light source, or the like.

The example device also comprises a camera 530 configured to capture an image from incident radiation 535, and controlled by the processor 510. In one example use case, the processor 510 may be configured to perform automatic white balancing of an image captured by the camera 530 in response to a color of radiation 515 sensed by the sensor 505.

FIG. 6 depicts a sensor 605 according to an embodiment of the disclosure, implemented in a Behind-Organic-LED (BOLED) display application. The sensor 605 may correspond to the sensor 505 of the device 500. The sensor 605 is disposed rearward of a radiation-emitting surface of an OLED display 620 and configured and receive radiation 615 propagating through the display 620. In the example of FIG. 6, the radiation 615 is sunlight.

Furthermore, the sensor 605 is be arranged such that radiation 615 to be sensed is incident on a backside of the sensor 605. Advantageously, by making use of backside illumination, enhanced sensitivity may be achieved while avoiding optical losses, especially at wavelengths of approximately 425 nanometers, e.g. blue light, due to nitride isolation layers implemented in advanced CMOS metal systems.

In the example BOLED display application, an optical device 645 such as a lens and/or diffuser is disposed between the OLED display 620 and the sensor 605. A first air gap 655 is provided between the OLED display 620 and the optical device 645, and a second air gap 660 is provided between the optical device 645 and the sensor 605.

A plurality of different interference filters 630 are formed on a backside of the sensor 605. In some embodiments, each interference filter 630 corresponds to a channel of the sensor 605, e.g. channels 305a-i of the sensor 300 of FIG. 3.

An indium tin oxide (ITO) layer 665 is formed over the interference filters 630.

For completeness, back-end-of-line (BEOL) layers 635, such as metal layers, insulating layers, any Metal-Insulator-Metal (MiM) structures, and/or poly-layers formed on a front-side of the sensor 605 are also shown. The sensor is mounted on a carrier substrate 640, e.g. a wafer.

In some embodiments, operation of the sensor 605 may be synchronized with the OLED display 620. For example, the sensor 605 may be configured to sense radiation 615 propagating through the OLED display 620 without interference from radiation emitted by the LED display 620. As such, an integration time may be selected to be sufficiently short to be synchronized with the OLED display 620. In some embodiments, the integration time may be selected to be 150 μs or less.

Although the disclosure has been described in terms of preferred embodiments as set forth above, it should be understood that these embodiments are illustrative only and that the claims are not limited to those embodiments. Those skilled in the art will be able to make modifications and alternatives in view of the disclosure, which are contemplated as falling within the scope of the appended claims. Each feature disclosed or illustrated in the present specification may be incorporated in any embodiments, whether alone or in any appropriate combination with any other feature disclosed or illustrated herein.

Reference Numerals

| | | | |
|---|---|---|---|
| 100 | active pixel | 300 | sensor |
| 105 | photodiode | 305a-i | channels |
| 110 | reset transistor | 310 | sample and hold circuitry |
| 115 | transfer transistor | 315 | comparators |
| 120 | floating diffusion region | 320 | ramp generator |
| 125 | source follower transistor | 325 | memory |
| 130 | row select transistor | 330 | counter |
| 150 | pinning layer | 335 | shift registers |
| 160 | voltage reference | 340 | accumulator |
| 200 | pixel | 400 | circuit |
| 205a-d | pinned photodiode | 405 | pixel |
| 210 | reset transistor | 410a-d | pinned photodiodes |
| 215a-d | transfer transistor | 415 | sample and hold circuit |
| 220 | floating diffusion region | 420 | floating diffusion |
| 225 | source-follower transistor | 425 | output buffer |
| 230 | circuitry | 430 | ADC |
| 235a-d | transfer gates | 500 | electronic device |
| 240 | gate | 505 | sensor |
| 245 | gate | 510 | processor |
| 250 | gate | 515 | incident radiation |
| 260 | voltage reference | 520 | display |
| 525 | radiation | 635 | back-end-of-line layers |
| 530 | camera | 640 | carrier substrate |
| 535 | incident radiation | 645 | optical device |
| 605 | sensor | 655 | first air gap |
| 615 | radiation | 660 | second air gap |
| 620 | OLED display | 665 | indium tin oxide layer |
| 630 | interference filter | | |

1. A sensor for ambient light and/or color sensing comprising:
a pixel comprising a plurality of pinned photodiodes selectively coupled to a floating diffusion region; and
circuitry configurable to select an integration time and to couple one or more of the plurality of pinned photodiodes to the floating diffusion region in response to a sensed intensity of radiation incident on the pixel.

2. The sensor of claim 1, wherein the integration time is selected such that a charge accumulated by the one or more pinned photodiodes is less than 75% of a full-well-charge capacity of each of the pinned photodiodes.

3. The sensor of claim 1, wherein the sensed intensity of radiation incident on the pixel is determined by the circuitry using data from a plurality of separate integrations.

4. The sensor of claim 1, wherein the integration time is 150 microseconds or less.

5. The sensor of claim 1, wherein each pinned photodiode comprises an active region having an area of at least 25 μm².

6. The sensor of claim 1, wherein the pixel comprises four pinned photodiodes arranged around the floating diffusion region.

7. The sensor of claim 1, comprising a plurality of pixels, wherein the circuitry is configured to average a signal from each pixel of the plurality of pixels prior to analog-to-digital conversion.

8. The sensor of claim 1, comprising a plurality of channels, each channel comprising at least one pixel, wherein each channel is configured to sense a different range of wavelengths of radiation.

9. The sensor of claim 8, wherein each channel comprises an interference filter configured as a band-pass filter.

10. The sensor of claim 1, formed as a monolithic device in a low-voltage CMOS process.

11. The sensor of claim 1, wherein the floating diffusion region is configured to have a capacitance of 2.5 Femtofarads, or less.

12. The sensor of claim 1, configured to exhibit a resolution of at least 18 bits and/or at least 27 bits of dynamic range.

13. An electronic device comprising the sensor of claim 1.

14. The electronic device of claim 13, wherein the sensor is configured for backside-illumination.

15. The electronic device of claim 13, comprising an LED display, wherein the sensor is disposed rearward of a radiation-emitting surface of the LED display and configured and receive radiation propagating through the LED display.
